(19) United States
(12) Patent Application Publication
(10) Pub. No.: US 2024/0065053 A1
(43) Pub. Date: Feb. 22, 2024

(54) Display Panel and Terminal Device

(71) Applicant: Honor Device Co., Ltd., Shenzhen (CN)

(72) Inventors: Lei Ma, Shenzhen (CN); Jiehua Tang, Shenzhen (CN); Peng Wang, Shenzhen (CN)

(21) Appl. No.: 18/260,659

(22) PCT Filed: May 16, 2022
(86) PCT No.: PCT/CN2022/092958

§ 371 Date: Jul. 7, 2023

(30) Foreign Application Priority Data
Aug. 5, 2021 (CN) 202110897949.6

(51) Int. Cl. H10K 59/131

(52) U.S. Cl. CPC H10K 59/131

(57) ABSTRACT

A display panel and a terminal device in the field of terminal technologies. A light-emitting component is disposed in each of a first display region and a second display region of the display panel, and a pixel drive circuit and a signal line are disposed only in the first display region, so that each pixel drive circuit is connected to the light-emitting component by using a bridge wire. Therefore, when the signal line in the first display region is connected to a drive chip by using a fan-out lead, a size of the fan-out lead located in a fan-out region can be reduced in a direction from a display region to a binding region, thereby reducing a frame width on a first side of the display panel.

This application claims priority to Chinese Patent Application No. 202110897949.6, filed with the China National Intellectual Property Administration on Aug. 5, 2021, and entitled “DISPLAY PANEL AND TERMINAL DEVICE”, which is incorporated herein by reference in its entirety.

### TECHNICAL FIELD

This application relates to the field of terminal technologies, and in particular, to a display panel and a terminal device.

### BACKGROUND

With the continuous development of the information era, terminal devices such as mobile phones have become commonly used tools in people's life and work, and terminal devices with a high screen-to-body ratio are favored by increasingly more consumers, so that the terminal devices with a high screen-to-body ratio gradually become the trend of the industry.

Currently, a drive chip and a fan-out lead are disposed in a frame region of a display panel of the terminal device. Consequently, a frame width on a side that is of the display panel and on which the drive chip is bound is large.

### SUMMARY

Embodiments of this application provide a display panel and a terminal device, to reduce a frame width on a side that is of the display panel and on which a drive chip is bound.

According to a first aspect, an embodiment of this application provides a display panel, where the display panel has a display region and a frame region surrounding the display region, the display region includes a first display region and a second display region located on at least one side of the first display region, and the second display region is located between the first display region and the frame region; the display panel includes a drive array layer, a first insulation layer, a bridge wire layer, a second insulation layer, and a light-emitting component layer that are stacked on a substrate; the drive array layer includes a plurality of pixel drive circuits and a plurality of signal lines extending in a first direction, each signal line is connected to pixel drive circuits located in a same column, and the pixel drive circuits and the signal lines at the drive array layer are distributed in the first display region; the light-emitting component layer includes a plurality of light-emitting components, a part of light-emitting components at the light-emitting component layer are located in the first display region, and another part of light-emitting components at the light-emitting component layer are located in the second display region; the bridge wire layer includes a plurality of bridge wires, each bridge wire is connected to the pixel drive circuit through a first via hole penetrating the first insulation layer, and each bridge wire is further connected to the light-emitting component through a second via hole penetrating the second insulation layer; and the frame region includes a fan-out region and a binding region that are located on a first side of the display region, the fan-out region is located between the binding region and the display region, a plurality of fan-out leads are disposed in the fan-out region, a drive chip is disposed in the binding region, one end of the fan-out lead extends in a direction of the signal line connected to the fan-out lead, and the other end of the fan-out lead extends in a direction of the drive chip connected to the fan-out lead.

In this way, the second display region may be located on one side, two opposite sides, or any three sides or four sides of the first display region. In this application, the pixel drive circuit is retracted, so that the pixel drive circuit and the signal line are disposed only in the first display region of the display panel, and the pixel drive circuit and the signal line are not disposed in the second display region. Therefore, when the signal line in the first display region is connected to the drive chip by using the fan-out lead, a size of the fan-out lead located in the fan-out region is reduced in a direction from the display region to the binding region, thereby reducing a frame width on the first side of the display panel.

In an optional implementation, the second display region is located on a first side of the first display region, and the fan-out lead passes through the second display region, and extends to a boundary between the first display region and the second display region. In this way, the pixel drive circuit needs to be retracted only in a direction from the first side to a second side, and the pixel drive circuit is retracted in fewer directions, so that a design difficulty of the pixel drive circuit can be reduced.

In an optional implementation, the second display region is located on each of a first side and a second side of the first display region, the first side and the second side are opposite to each other, and the fan-out lead passes through the second display region located on the first side, and extends to a boundary between the first display region and the second display region located on the first side. In this way, a frame width on the second side of the display panel may be reduced while the frame width on the first side of the display panel is reduced.

In an optional implementation, the second display region is located on each of a third side and a fourth side of the first display region, the third side and the fourth side are opposite to each other, both the third side and the fourth side are adjacent to the first side, and the fan-out lead is distributed in the fan-out region, and is connected to the signal line at a boundary between the fan-out region and the first display region. In this way, frame widths on the third side and the fourth side of the display panel may be reduced while the frame width on the first side of the display panel is reduced.

In an optional implementation, the second display region is located on three sides of the first display region; and the display region includes at least the second display region located on a first side of the first display region, and the fan-out lead passes through the second display region located on the first side, and extends to a boundary between the first display region and the second display region located on the first side, or the display region includes the second display regions located on a second side, a third side, and a fourth side of the first display region, and the fan-out lead is distributed in the fan-out region, and is connected to the signal line at a boundary between the fan-out region and the first display region. In this way, a frame width on another side of the display panel may be reduced while the frame width on the first side of the display panel is reduced.

In an optional implementation, the second display region surrounds the first display region, and the fan-out lead passes through the second display region located on the first side, and extends to a boundary between the first display region and the second display region located on the first side. In this way, frame widths on the second side, third side, and the fourth side of the display panel may be reduced while the frame width on the first side of the display panel is reduced.

In an optional implementation, a difference between quantities of light-emitting components through which any two bridge wires pass is less than a preset quantity. In this way, uniformity of display brightness of the display panel can be improved.

In an optional implementation, an orthographic projection of each bridge wire on the substrate is any one or a combination of a plurality of a straight line, a broken line, and a curve. In this way, specific shapes of a plurality of different bridge wires can be provided.

In an optional implementation, a total distribution region of the fan-out lead in the display panel includes a central sub-region and a first edge sub-region and a second edge sub-region that are located on two sides of the central sub-region, the first edge sub-region, the central sub-region, and the second edge sub-region are sequentially distributed in a second direction, and the second direction and the first direction are perpendicular to each other; the fan-out lead in the central sub-region includes a first straight line segment extending in the first direction; and the fan-out leads in the first edge sub-region and the second edge sub-region each include a second straight line segment, an oblique line segment, and a third straight line segment that are sequentially connected, the second straight line segment and the third straight line segment both extend in the first direction, the second straight line segment is close to the first display region, the third straight line segment is close to the binding region, and an included angle between the oblique line segment and the first direction is an acute angle.

In an optional implementation, included angles between the oblique line segments of the fan-out leads in the first edge sub-region and the first direction gradually increase in a direction from the central sub-region to the first edge sub-region, and included angles between the oblique line segments of the fan-out leads in the second edge sub-region and the first direction gradually increase in a direction from the central sub-region to the second edge sub-region; and for the fan-out leads in the first edge sub-region and the second edge sub-region, a line segment formed by connection points between the second straight line segments and the oblique line segments is parallel to the second direction, and a line segment formed by connection points between the third straight line segments and the oblique line segments is also parallel to the second direction. In this implementation, a specific distribution structure of the fan-out lead is provided.

In an optional implementation, included angles between the first direction and the oblique line segments of the fan-out leads in the first edge sub-region and the second edge sub-region are equal; and for the fan-out leads in the first edge sub-region and the second edge sub-region, a line segment formed by connection points between the second straight line segments and the oblique line segments is parallel to the second direction, and an included angle between the first direction and a line segment formed by the connection points between the third straight line segments and the oblique line segments is an obtuse angle. In this implementation, another specific distribution structure of the fan-out lead is provided.

In an optional implementation, a difference between resistance values of any two fan-out leads is less than a preset resistance value. In this way, a problem of color cast and non-uniform brightness of a display picture in a display process can be alleviated, and a display effect can be improved.

In an optional implementation, line widths of the fan-out leads are equal, the fan-out lead in the central sub-region further includes a first winding segment connected to the first straight line segment, at least a part of fan-out leads in the first edge sub-region and the second edge sub-region further include a second winding segment, and the second winding segment is connected to any one of the second straight line segment, the oblique line segment, and the third straight line segment; and a length of the first winding segment is greater than a length of the second winding segment, lengths of the second winding segments of the fan-out leads in the first edge sub-region gradually decrease in a direction from the central sub-region to the first edge sub-region, and lengths of the second winding segments of the fan-out leads in the second edge sub-region gradually decrease in a direction from the central sub-region to the second edge sub-region. In this way, when the line widths of the fan-out leads remain unchanged, a fan-out lead with a short length is wound, so that lengths of the fan-out leads in the display panel are basically the consistent, and resistance values of the fan-out leads are close to each other.

In an optional implementation, line widths of the fan-out leads in the first edge sub-region gradually increase in a direction from the central sub-region to the first edge sub-region, and line widths of the fan-out leads in the second edge sub-region gradually increase in a direction from the central sub-region to the second edge sub-region. In this way, when the lengths of the fan-out lead remain unchanged, a line width of a fan-out lead with a long length is increased, so that resistance values of the fan-out leads are close to each other.

In an optional implementation, orthographic projections, on the substrate, of each light-emitting component distributed in the first direction and a pixel defining structure between two adjacent light-emitting components in the first direction cover an orthographic projection of the signal line on the substrate. In this way, a reflection problem of the display panel in a screen-off state can be alleviated.

In an optional implementation, two adjacent light-emitting components are spaced apart by using a pixel defining structure, a gap exists between two adjacent pixel drive circuits, and transistors included in the pixel drive circuit are disposed at a same layer; and in a direction from the second display region to the first display region, a sum of a size of the pixel drive circuit and a size of the gap is less than a sum of a size of the light-emitting component and a size of the pixel defining structure. In this way, a size of a transistor in each pixel drive circuit and/or a size of a gap between two adjacent pixel drive circuits are/is reduced, to retract the pixel drive circuit without changing a thickness of the display panel.

In an optional implementation, each pixel drive circuit includes a first transistor group and a second transistor group, and the first transistor group and the second transistor group each include at least one transistor; and the second transistor is disposed on a side that is of the first transistor group and that is away from the substrate, and an orthographic projection of each transistor in the second transistor group on the substrate and an orthographic projection of each transistor in the first transistor group on the substrate have an overlapping region. In this way, the transistors in the pixel drive circuit are disposed at different layers, so that an area occupied by each pixel drive circuit is reduced in a thickness direction, to retract the pixel drive circuit. In this case, there is no need to reduce a size of each transistor and a size of a gap between two adjacent pixel drive circuits, thereby reducing a manufacture difficulty of the pixel drive circuit.

According to a second aspect, an embodiment of this application provides a terminal device, including a housing and the foregoing display panel. The display panel is mounted on the housing.

It should be understood that technical solutions of the second aspect in this application correspond to technical solutions of the first aspect in this application, and beneficial effects achieved by the aspects and corresponding feasible implementations are similar. Details are not described again.

### BRIEF DESCRIPTION OF DRAWINGS

FIG. 1 is a schematic diagram of a structure of a display panel in the related technology;

FIG. 2 is a schematic diagram of a structure of a terminal device according to an embodiment of this application:

FIG. 3 is a schematic diagram of a structure of a first display panel according to an embodiment of this application;

FIG. 4 is a schematic distribution diagram of a pixel drive circuit in the display panel shown in FIG. 3;

FIG. 5 is a partial enlarged schematic view of a region A of the display panel shown in FIG. 3;

FIG. 6 is a cutaway drawing of the display panel shown in FIG. 5 along a cross section L-L′;

FIG. 7 is a schematic diagram of a principle of reducing a frame width after a pixel drive circuit of the display panel shown in FIG. 3 is retracted in a second direction;

FIG. 8 is a schematic distribution diagram of a pixel drive circuit in a second display panel according to an embodiment of this application;

FIG. 9 is a schematic distribution diagram of a pixel drive circuit in a third display panel according to an embodiment of this application;

FIG. 10 is a schematic distribution diagram of a pixel drive circuit in a fourth display panel according to an embodiment of this application;

FIG. 11 is a schematic distribution diagram of a pixel drive circuit in a fifth display panel according to an embodiment of this application;

FIG. 12 is a partial enlarged schematic view of a first fan-out lead according to an embodiment of this application;

FIG. 13 is a partial enlarged schematic view of a second fan-out lead according to an embodiment of this application; and

FIG. 14 is a partial enlarged schematic view of a third fan-out lead according to an embodiment of this application.

### DESCRIPTION OF EMBODIMENTS

To clearly describe technical solutions in embodiments of this application, in embodiments of this application, words such as “first” and “second” are used to distinguish between same items or similar items with basically the same functions and effects. For example, a first chip and a second chip are merely intended to distinguish between different chips, and a sequence of the first chip and the second chip is not limited. A person skilled in the art may understand that the words such as “first” and “second” do not limit a quantity and an execution sequence, and the words such as “first” and “second” do not indicate a definite difference.

It should be noted that in embodiments of this application, a word such as “exemplarily” or “for example” is used to represent an example, an illustration, or a description. Any embodiment or design solution described as “exemplarily” or “for example” in this application should not be construed as more preferred or advantageous than other embodiments or design solutions. Exactly, use of the word such as “exemplarily” or “for example” is intended to present related concepts in a specific manner.

In embodiments of this application, “at least one” means one or more, and “a plurality of” means two or more. The term “and/or” describes an association relationship between associated objects, and indicates that three relationships may exist. For example, A and/or B may indicate the following cases: Only A exists, both A and B exist, and only B exists, where A and B may be singular or plural. The character “/” usually indicates an “or” relationship between the associated objects. “At least one of the following items” or a similar expression means any combination of these items, including any combination of a single item or a plurality of items. For example, at least one of a, b, or c may represent a, b, c, a-b, a-c, b-c, or a-b-c, where a, b, and c may be singular or plural.

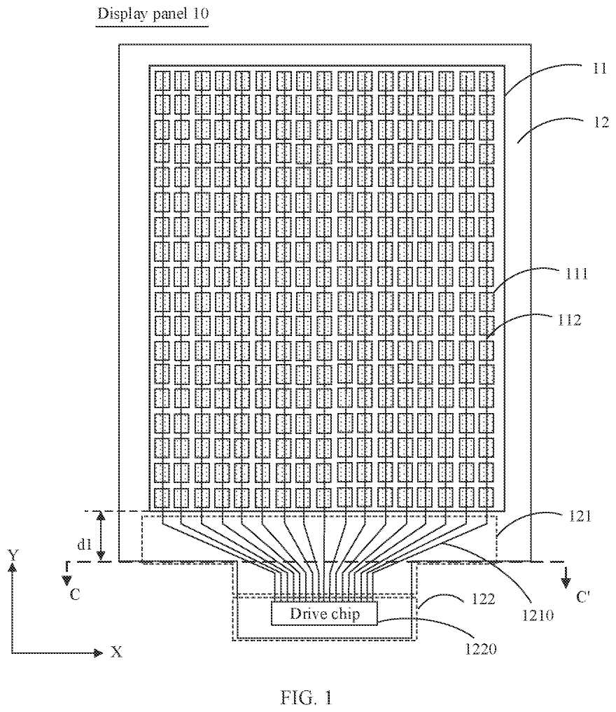

In the related technology, as shown in FIG. 1, a display panel 10 includes a display region 11 and a frame region 12 surrounding the display region 11. The frame region 12 includes a fan-out region 121 and a binding region 122 that are disposed on one side of the display region 11, and the fan-out region 121 is located between the binding region 122 and the display region 11.

A plurality of sub-pixels 111 are disposed in the display region 11. Each sub-pixel 111 includes a pixel drive circuit and a light-emitting component connected to the pixel drive circuit. A same column of pixel drive circuits are connected to a same signal line 112. The signal line 112 extends in a first direction Y. In a direction from a light exit side of the display panel 10 to a backlight side thereof, orthographic projections of the pixel drive circuit and the light-emitting component connected to the pixel drive circuit basically overlap.

A drive chip 1220 is disposed in the binding region 122. Because a size of the drive chip 1220 in a second direction X is less than a size of the display region 11 in the second direction X, and the second direction X is a row direction of the display panel 10, a plurality of fan-out leads 1210 need to be disposed in the fan-out region 121, so that the drive chip 1220 is connected to the signal line 112 by using the fan-out lead 1210. A drive signal provided by the drive chip 1220 is transmitted to the signal line 112 by using the fan-out lead 1210, and the drive signal is provided to a same column of pixel drive circuits by using the signal line 112.

As a result, both a size of the fan-out region 121 in the first direction Y and a size of the binding region 122 in the first direction Y affect a frame width on a first side of the display panel 10, resulting in a large frame width on the first side of the display panel 10. The first side is a side that is of the display region 11 and that faces the binding region 122. To reduce the frame width on the first side of the display panel 10, in the related technology, bending may be performed at the fan-out region 121, so that the drive chip 1220 and some line segments of the fan-out leads 1210 are bent to the back side (a side opposite to the light exit side of the display panel 10) of the display panel 10, to reduce the frame width on the first side of the display panel 10. A bending line C-C′ existing when the fan-out region 121 is bent is parallel to the second direction X.

However, on the light exit side of the display panel 10, most line segments of the fan-out leads 1210 are still located in the frame region 12. As a result, a size of the fan-out region 121 left on the light exit side of the display panel 10 is still large in the first direction Y. and consequently the frame width d1 on the first side of the display panel 10 is still large.

Based on this, embodiments of this application provide a display panel. A pixel drive circuit is retracted, so that the pixel drive circuit and a signal line are disposed only in a first display region of the display panel, and the pixel drive circuit and the signal line are not disposed in a second display region. Therefore, when the signal line in the first display region is connected to a drive chip by using a fan-out lead, a size of the fan-out lead located in the fan-out region is reduced in a direction from a display region to a binding region, thereby reducing a frame width on a first side of the display panel.

The display panel provided in the embodiments of this application may be applied to a terminal device having a display function. The terminal device may be a device such as a mobile phone, a tablet computer, an electronic reader, a notebook computer, a vehicle-mounted device, a wearable device, or a television.

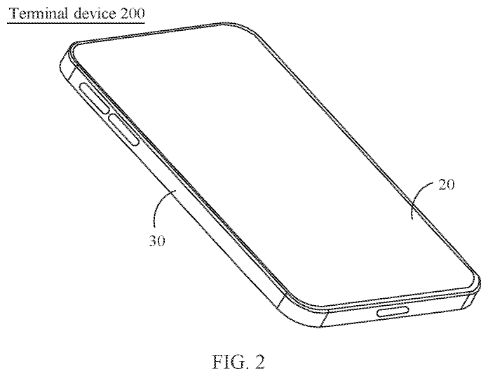

As shown in FIG. 2, a terminal device 200 includes a display panel 20 and a housing 30. The display panel 20 is mounted on the housing 30, and is configured to display an image, a video, or the like. The display panel 20 and the housing 30 jointly enclose an accommodating cavity of the terminal device 200, to place an electronic component and the like of the terminal device 200 by using the accommodating cavity, and seal and protect the electronic component located in the accommodating cavity. For example, a circuit board, a battery, and the like of the terminal device 200 are located in the accommodating cavity.

The following describes, in detail by using specific embodiments, the technical solutions of this application and how the foregoing technical problems are resolved by using the technical solutions of this application. The following several specific embodiments may be implemented independently, or may be combined with each other. For same or similar concepts or processes, details may not be described again in some embodiments.

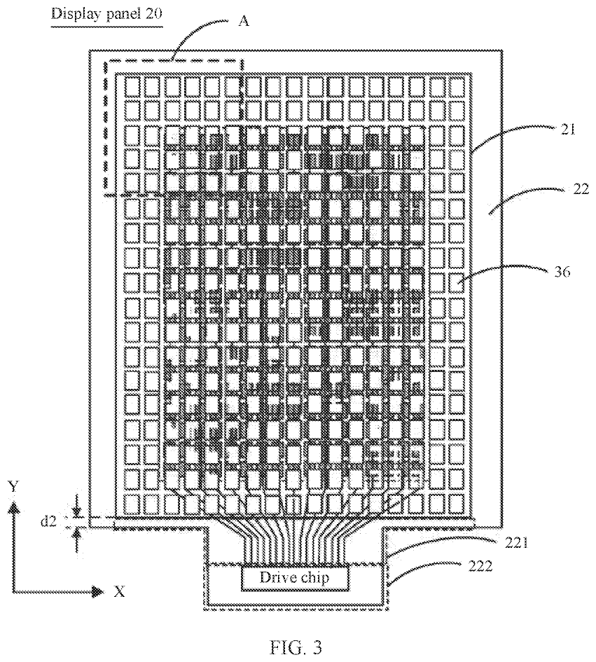

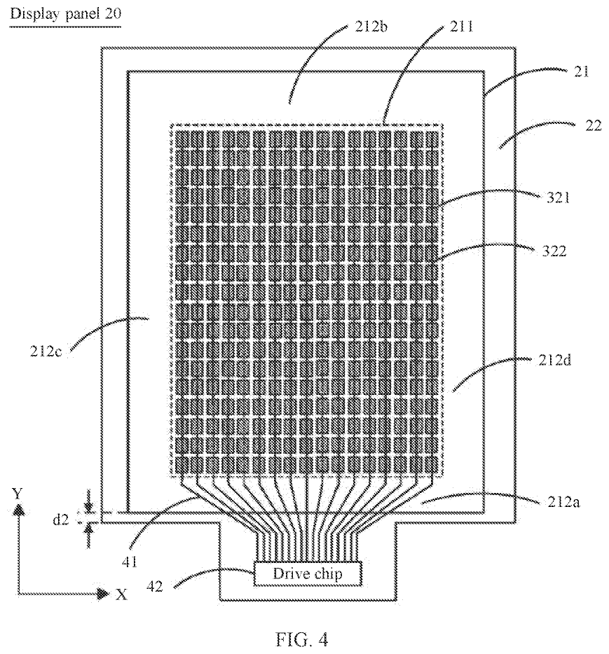

For example, FIG. 3 is a schematic diagram of a structure of a first display panel according to an embodiment of this application, and FIG. 4 is a schematic distribution diagram of a pixel drive circuit in the display panel shown in FIG. 3. As shown in FIG. 3 and FIG. 4, the display panel 20 has a display region 21 and a frame region 22 surrounding the display region 21. The frame region 22 includes a fan-out region 221 and a binding region 222 that are located on a first side of the display region 21. The fan-out region 221 is located between the binding region 222 and the display region 21. The display region 21 includes a first display region 211 and a second display region surrounding the first display region 211. The second display region surrounding the first display region 211 is respectively; a second display region 212a located on a first side of the first display region 211, a second display region 212b located on a second side of the first display region 211, a second display region 212c located on a third side of the first display region 211, and a second display region 212d located on a fourth side of the first display region 211.

The first side is a side that is of the first display region 211 and that faces the binding region 222, that is, the first side is a lower side in FIG. 3 and FIG. 4. The second side is a side that is of the first display region 211 and that faces away from the binding region 222, and the second side is opposite to the first side, that is, the second side is an upper side in FIG. 3 and FIG. 4. The third side is a side adjacent to both the first side and the second side, that is, the third side may be a left side in FIG. 3 and FIG. 4. The fourth side is another side adjacent to both the first side and the second side, and the fourth side is opposite to the third side, that is, the fourth side may be a right side in FIG. 3 and FIG. 4.

In this case, the frame region 22 actually surrounds the second display region, so that the second display region 212a located on the first side, the second display region 212b located on the second side, the second display region 212c located on the third side, and the second display region 212d located on the fourth side are all between the first display region 211 and the frame region 22.

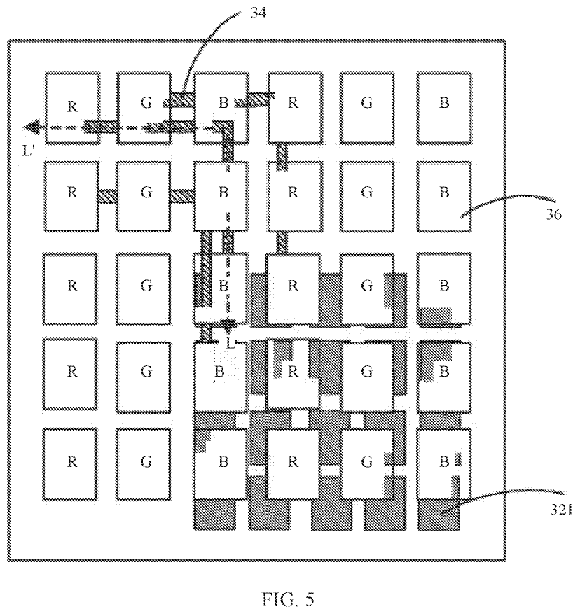

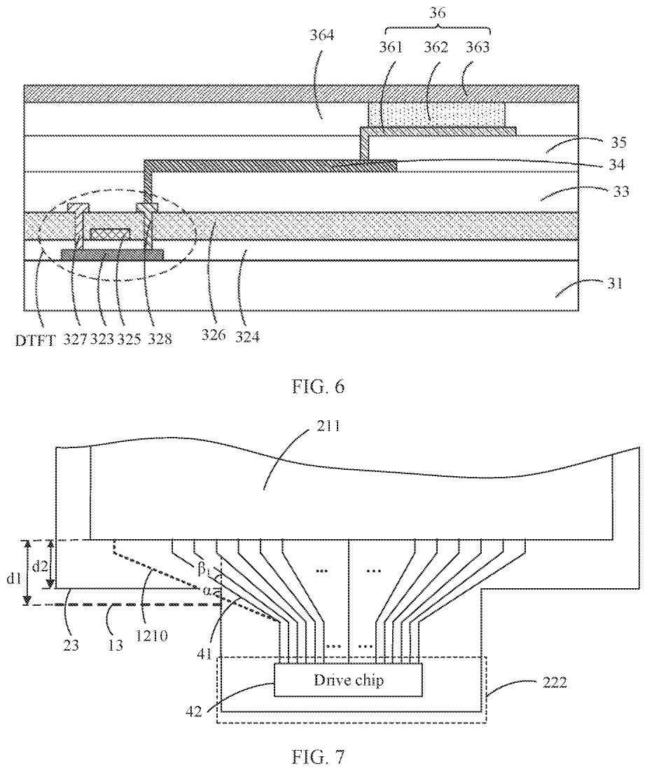

FIG. 5 is a partially enlarged schematic view of a region A in the display panel shown in FIG. 3. FIG. 6 is a cutaway drawing of the display panel shown in FIG. 5 along a cross section L-L′. As shown in FIG. 6, the display panel 20 includes a drive array layer, a first insulation layer 33, a bridge wire layer, a second insulation layer 35, and a light-emitting component layer that are stacked on a substrate 31.

In an actual product, the substrate 31 may be a flexible substrate such as a polyimide (polyimide, PI) substrate, or the substrate 31 may be a rigid substrate such as a glass substrate.

The drive array layer is disposed on one surface of the substrate 31, and the drive array layer includes an active layer, a gate insulation layer 324, a gate layer, an interlayer medium layer 326, and a source/drain electrode layer that are sequentially stacked on the substrate 31. Based on an active pattern included in the active layer, a gate pattern included in the gate layer, and a conductive pattern included in the source/drain electrode layer, a plurality of pixel drive circuits 321 included in the drive array layer and signal transmission wires connected to the pixel drive circuits 321 may be manufactured.

The signal transmission wires include a plurality of signal lines 322 extending in a first direction Y, and the signal line 322 may be a data line used to transmit a data signal to a pixel drive circuit connected to the signal line, and may be located at the source/drain electrode layer. In addition, the signal transmission wires further include a plurality of gate lines (not shown) extending in a second direction X, a plurality of reset signal lines (namely, Reset signal lines) extending in the second direction X, a plurality of light-emitting control signal lines (namely, EM signal lines) extending in the second direction X, a plurality of supply voltage signal lines (namely, VDD signal lines) extending in the first direction Y, and the like. The gate lines, the reset signal lines, and the light-emitting control signal lines may be located at the gate layer, and the supply voltage signal lines may be located at the source/drain electrode layer. The first direction Y may be a column direction of the display panel 20, or the first direction Y may be a direction from the display region 21 to the binding region 222. The second direction X may be a row direction of the display panel 20. The first direction Y and the second direction X may be perpendicular.

Each pixel drive circuit 321 includes a storage capacitor and a plurality of transistors such as a reset transistor, a data write transistor, a light-emitting control transistor, and a drive transistor. The cutaway drawing shown in FIG. 6 shows only a specific structure of one transistor, and does not show a structure of another transistor. For example, the transistor may be a drive transistor DTFT, an active pattern 323 of the drive transistor DTFT is located at the active layer, a gate 325 of the drive transistor DTFT is located at the gate layer, and a source 327 and a drain 328 of the drive transistor DTFT are located at the source/drain electrode layer.

In an actual product, the plurality of pixel drive circuits 321 included in the drive array layer are distributed in an array, and pixel drive circuits 321 located in a same column are connected to a same signal line 322. Correspondingly, pixel drive circuits 321 located in a same row are connected to a same gate line, a same reset signal line, and a same light-emitting control signal line.

It should be noted that, each signal line 322 may be located between two adjacent columns of pixel drive circuits 321, or each signal line 322 may be located in a region in which a same column of pixel drive circuits 321 connected to the signal line 322 are located. This is not limited in this embodiment of this application.

The light-emitting component layer includes a plurality of light-emitting components 36. The plurality of light-emitting components 36 are distributed in an array. Each light-emitting component 36 includes a first electrode 361, a light-emitting layer 362, and a second electrode 363 that are stacked. The light-emitting layer 362 is located between the first electrode 361 and the second electrode 363. For example, the first electrode 361 may be an anode, and the second electrode 363 may be a cathode.

The light-emitting components 36 at the light-emitting component layer are classified into a red light-emitting component (R light-emitting component), a blue light-emitting component (B light-emitting component), a green light-emitting component (G light-emitting component), and the like. The light-emitting component 36 may be an organic light-emitting diode (organic light-emitting diode, OLED) a Miniled (mini light-emitting diode), a MicroLed (micro light-emitting diode), a quantum dot light-emitting diode (quantum dot light emitting diodes, QLED), and the like.

To reduce a frame width on a first side of the display panel 20, in this embodiment of this application, each pixel drive circuit 321 at the drive array layer is retracted toward a central region of the display panel 20 in the first direction Y and the second direction X, so that the pixel drive circuits 321 and the signal lines 322 are distributed in the first display region 211. However, a position of each light-emitting component 36 at the light-emitting component layer remains unchanged, so that a part of light-emitting components 36 at the light-emitting component layer are located in the first display region 211, and another part of light-emitting components 36 at the light-emitting component layer are located in the second display region. In this case, the light-emitting components 36 are distributed in both the first display region 211 and the second display region. That is, in FIG. 3, the light-emitting components 36 are distributed in the first display region 211, the second display region 212a located on the first side, the second display region 212b located on the second side, the second display region 212c located on the third side, and the second display region 212d located on the fourth side.

Each pixel drive circuit 321 needs to be connected to a corresponding light-emitting component 36, to drive the light-emitting component 36 to emit light. However, when each pixel drive circuit 321 is retracted toward the central region of the display panel 20 in the first direction Y and the second direction X, and the position of the light-emitting component 36 remains unchanged, there is no overlapping region between orthographic projections of a part of light-emitting components 36 on the substrate 31 and orthographic projections of pixel drive circuits 321 connected to the light-emitting components 36 on the substrate 31. Therefore, a bridge wire needs to be additionally added to connect the pixel drive circuit 321 and the light-emitting component 36.

However, due to limited wiring space of the source/drain electrode layer of the drive array layer, there is no redundant space at the source/drain electrode layer to dispose a bridge wire to connect the pixel drive circuit 321 and the light-emitting component 36. Therefore, in this embodiment of this application, a bridge wire layer is added between the drive array layer and the light-emitting component layer. The bridge wire layer includes a plurality of bridge wires 34, one end of the bridge wire 34 extends in a direction of the pixel drive circuit 321, and the other end of the bridge wire 34 extends in a direction of the light-emitting component 36 connected to the pixel drive circuit 321.

In addition, to prevent the bridge wire 34 from being in direct contact with the conductive pattern in the pixel drive circuit 321 and the first electrode 361 of the light-emitting component 36, the first insulation layer 33 is disposed between the bridge wire layer and the drive array layer, and the second insulation layer 35 is disposed between the bridge wire layer and the light-emitting component layer. Materials of the first insulation layer 33 and the second insulation layer 35 may be organic insulating materials, or may be inorganic insulating materials such as silicon nitride or silicon oxide.

Therefore, if the pixel drive circuit 321 and the light-emitting component 36 needs to be connected by using the bridge wire 34, one end of the bridge wire 34 needs to be connected to the pixel drive circuit 321 through a first via hole penetrating through the first insulation layer 33, and the other end of the bridge wire 34 needs to be connected to the light-emitting component 36 through a second via hole penetrating through the second insulation layer 35.

For example, in some embodiments, the drain of the drive transistor DTFT in the pixel drive circuit 321 is directly connected to the first electrode 361 of the light-emitting component 36. In this case, one end of the bridge wire 34 may be connected to the drain 328 of the drive transistor DTFT in the pixel drive circuit 321 through the first via hole penetrating the first insulation layer 33, and the other end of the bridge wire 34 may be connected to the first electrode 361 of the light-emitting component 36 through the second via hole penetrating the second insulation layer 35. In some other embodiments, a light-emitting control transistor is further connected in series between the drain of the drive transistor DTFT in the pixel drive circuit 321 and the first electrode 361 of the light-emitting component 36, and is turned on under the action of the light-emitting control signal line, so that a drive current of the drive transistor DTFT can flow to the first electrode 361 of the light-emitting component 36. In this case, one end of the bridge wire 34 may be connected to a drain of the light-emitting control transistor in the pixel drive circuit 321 through the first via hole penetrating the first insulation layer 33, the other end of the bridge wire 34 may be connected to the first electrode 361 of the light-emitting component 36 through the second via hole penetrating the second insulation layer 35, and a source of the light-emitting control transistor is connected to the drain of the drive transistor DTFT.

In an actual manufacture process, after the drive array layer is formed on the substrate 31, first, the first insulation layer 33 that covers the drive array layer needs to be formed; next, patterning processing is performed on the first insulation layer 33 to form the first via hole penetrating the first insulation layer 33; and subsequently, the bridge wires 34 are formed on the first insulation layer 33. When the bridge wire 34 is formed, a material of the bridge wire 34 is deposited in the first via hole, so that the bridge wire 34 disposed on the first insulation layer 33 is connected to the pixel drive circuit 321 through the first via hole penetrating the first insulation layer 33. For example, a material of the first insulation layer 33 is an inorganic material, and patterning processing includes process steps such as photoresist coating, exposure, developing, and etching.

After the bridge wire layer is formed, the second insulation layer 35 that covers the bridge wire layer and the first insulation layer 33 may be formed, patterning processing is performed on the second insulation layer 35 to form the second via hole penetrating the second insulation layer 35, and then the first electrode 361 corresponding to each light-emitting component 36 is formed on the second insulation layer 35. When the first electrode 361 corresponding to each light-emitting component 36 is formed, a material of the first electrode 361 is deposited in the second via hole, so that the first electrode 361 on the second insulating layers 35 is connected to the bridge wire 34 through the second via hole penetrating the second insulating layer 35, that is, the bridge wire 34 is connected to the first electrode 361 of the light-emitting component 36 through the second via hole penetrating the second insulating layer 35.

An orthographic projection of the first via hole on the substrate 31, an orthographic projection of the bridge wire 34 on the substrate 31, and an orthographic projection, on the substrate 31, of the drain that is of the transistor in the pixel drive circuit 321 and that is connected to the bridge wire 34 have at least a partially overlapping region. Correspondingly, an orthographic projection of the second via hole on the substrate 31, an orthographic projection of the bridge wire 34 on the substrate 31, and an orthographic projection of the first electrode 361 of the light-emitting component 36 on the substrate 31 have at least a partially overlapping region.

As shown in FIG. 3 and FIG. 4, to input a corresponding drive signal to the signal line 322 connected to the pixel drive circuit 321, a drive chip 42 needs to be disposed in the binding region 222, and a plurality of fan-out leads 41 need to be disposed in the fan-out region 221, so that the drive chip 42 is connected to the signal line 322 by using the fan-out lead 41.

When each pixel drive circuit 321 in the display panel 20 is retracted toward the central region of the display panel 20 in the first direction Y and the second direction X, one end of the fan-out lead 41 located in the fan-out region 221 needs to extend in a direction of the signal line 322 connected to the fan-out lead 41. In this case, because the signal line 322 is distributed only in the first display region 211, the fan-out lead 41 located in the fan-out region 221 needs to pass through the second display region 212a located on the first side, and extend to a boundary between the first display region 211 and the second display region 212a located on the first side. The fan-out lead 41 is connected to the signal line 322 at the boundary between the first display region 211 and the second display region 212a located on the first side.

The other end of the fan-out lead 41 located in the fan-out region 221 extends in a direction of the drive chip 42 connected to the fan-out lead 41, and specifically extends in a direction of a position of a pin of the drive chip 42 connected to the fan-out lead 41.

For the display panel 20 shown in FIG. 3 and FIG. 4, each pixel drive circuit 321 in the display panel 20 is retracted toward the central region of the display panel 20 in the first direction Y and the second direction X, to reduce a size, in the first direction Y. of the fan-out lead 41 located in the fan-out region 221, thereby reducing the frame width on the first side of the display panel 20. In this case, the frame width d2 on the first side of the display panel 20 is less than the frame width d1 on the first side of the display panel 10 shown in FIG. 1.

A specific reason is as follows: When each pixel drive circuit 321 is retracted toward the central region of the display panel 20 in the first direction Y, a partial line segment of the fan-out lead 41 may be moved to the second display region 212a located on the first side, so that a size of a line segment of the fan-out lead 41 left in the fan-out region 221 is reduced in the first direction Y. and correspondingly, a size of the fan-out region 221 is reduced in the first direction Y. If a size of the fan-out region 221 that needs to be bent to the back side of the display panel 20 remains unchanged in the first direction Y, a size of the fan-out region 221 left on the light exit side of the display panel 20 is reduced in the first direction Y, that is, a distance between a bending line and a boundary that is of the second display region 212a located on the first side and that faces away from the first display region 211 is reduced in the first direction Y, thereby reducing the frame width on the first side of the display panel 20.

In addition, when each pixel drive circuit 321 is retracted toward the central region of the display panel 20 in the second direction X, an included angle between the first direction Y and an oblique line segment of the fan-out lead 41 connected to each signal line 322 close to edges of the third side and the fourth side of the display region 21 may be reduced, so that the oblique line segment of the fan-out lead 41 connected to each signal line close to the edges of the third side and the fourth side of the display region 21 is closer to the first display region 211 in the first direction Y.

For example, as shown in FIG. 7, 1210 represents a fan-out lead 1210 connected to a signal line 112 (namely, a signal line located in the first column in a direction from the third side to the fourth side) closest to the edge position of the third side of the display region 11 in the display panel 10 shown in FIG. 1. In the related technology, an included angle between an oblique line segment of the fan-out lead 1210 and the first direction Y is a. However, in this embodiment of this application, after each pixel drive circuit 321 is retracted toward the central region of the display panel 20 in the second direction X, an included angle between the first direction Y and a fan-out lead 41 (namely, a signal line 322 located in the first column in the direction from the third side to the fourth side) connected to a signal line 322 closest to the edge position of the third side of the display region 21 of the display panel 20 is β₁, and β₁ is less than α. A first intersection point exists between the fan-out lead 1210 and an extension line, in the first direction Y, of an edge that is of the binding region 222 and that faces the third side of the display panel 20, a second intersection point exists between the fan-out lead 41 in FIG. 7 and the extension line, and the second intersection point is closer to the first display region 211 than the first intersection point.

The frame width on the first side of the display panel 20 needs to be determined based on the fan-out leads 41 connected to the signal lines 322 closest to the edge positions of the third side and the fourth side of the display region 21 of the display panel 20, and it is ensured that oblique line segments of the fan-out leads 41 connected to the signal lines 322 closest to the edge positions of the third side and the fourth side of the display region 21 do not exceed an edge 23 that is of a region other than the binding region 222 on the first side of the display panel 20 and that extends in the second direction X. Therefore, in this embodiment of this application, when the oblique line segment of the fan-out lead 41 connected to the signal line 322 is closer to the first display region 211 in the first direction Y, the edge 23 that is of the region other than the binding region 222 on the first side of the display panel 20 and that extends in the second direction X may be moved in a direction of the first display region 211, so that a distance between the first display region 211 and the edge 23 that is of the region other than the binding region 222 on the first side of the display panel 20 and that extends in the second direction X is shortened, thereby reducing the frame width on the first side of the display panel 20.

For example, as shown in FIG. 7, 13 represents an edge that is of a region other than the binding region on the first side of the display panel 10 shown in FIG. 1 and that extends in the second direction X. It can be learned that, to ensure that the oblique line segments of the fan-out leads connected to the signal lines closest to the edge positions of the third side and the fourth side of the display region do not exceed the edge that is of the region other than the binding region on the first side of the display panel and that extends in the second direction X, the edge 23 that is of the region other than the binding region 222 on the first side of the display panel 20 in this embodiment of this application and that extends in the second direction X is closer to the first display region 211 than the edge 13 that is of the region other than the binding region on the first side of the display panel 10 in the related technology and that extends in the second direction X, so that a distance (namely, the frame width d2 on the first side of the display panel 20) between the first display region 211 and the edge 23 that is of the region other than the binding region 222 on the first side of the display panel 20 in this embodiment of this application and that extends in the second direction X is less than a distance (namely, the frame width d1 on the first side of the display panel 10 in the related technology) between the first display region 211 and the edge 13 that is of the region other than the binding region on the first side of the display panel 10 in the related technology and that extends in the second direction X.

It should be noted that, in the display panel 20 in this embodiment of this application, the fan-out lead 1210 and the edge 13 actually do not exist. FIG. 7 shows the fan-out lead 1210 and the edge 13, only to more clearly describe a principle that the frame width on the first side of the display panel 20 is reduced after the pixel drive circuit 321 is retracted toward the central region of the display panel 20 in the second direction X.

In addition, each pixel drive circuit 321 in the display panel 20 is retracted toward the central region of the display panel 20 in the first direction Y and the second direction X, to reduce the frame width on the first side of the display panel 20, so that frame widths on the second side, the third side, and the fourth side of the display panel 20 can be further reduced.

For example, in the related technology, a gate driver on array (gate driver on array, GOA) circuit, for example, a Gate GOA circuit, an EM GOA circuit, and a Reset GOA circuit, is disposed in a frame region on the third side and/or the fourth side of the display panel, causing a large width of the frame region on the third side and/or the fourth side of the display panel. Therefore, in this embodiment of this application, after each pixel drive circuit 321 is retracted toward the central region of the display panel 20 in the second direction X, at least a partial structure in the GOA circuit may be moved to the second display region 212c located on the third side and the second display region 212d located on the fourth side, to reduce a width occupied by the GOA circuit in the frame regions 22 on the third side and the fourth side, thereby reducing the frame widths on the third side and the fourth side of the display panel 20.

In the related technology, a clock signal line or the like is further disposed in a frame region on the second side of the display panel, the clock signal line is used to provide a clock signal for the GOA circuit, and the clock signal line causes a large width of the frame region on the second side of the display panel. Therefore, in this embodiment of this application, after each pixel drive circuit 321 is retracted toward the central region of the display panel 20 in the first direction Y, the clock signal line may be moved to the second display region 212b located on the second side, to reduce the frame width on the second side of the display panel 20.

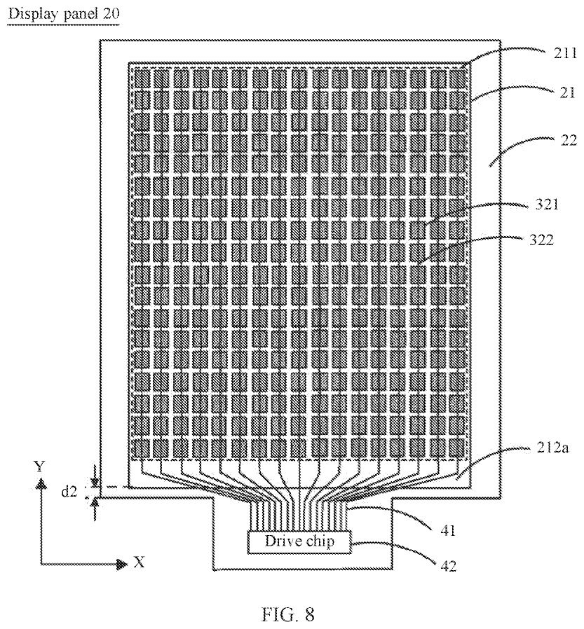

For example. FIG. 8 is a schematic distribution diagram of a pixel drive circuit in a second display panel according to an embodiment of this application. As shown in FIG. 8, a display panel 20 has a display region 21 and a frame region 22 surrounding the display region 21. The display region 21 includes a first display region 211 and a second display region 212a located on a first side of the first display region 211. The second display region 212a located on the first side of the first display region 211 is disposed between the first display region 211 and the frame region 22.

The frame region 22 includes a fan-out region 221 and a binding region 222 that are located on a first side of the display region 21, and the fan-out region 221 is located between the binding region 222 and the display region 21. Specifically, the first display region 211, the second display region 212a located on the first side, the fan-out region 221, and the binding region 222 are sequentially distributed in a first direction Y.

To reduce a frame width on a first side of the display panel 20, in this embodiment of this application, each pixel drive circuit 321 at a drive array layer is retracted toward a second side of the display panel 20, so that the pixel drive circuits 321 and the signal lines 322 are distributed in the first display region 211. However, a position of each light-emitting component 36 at a light-emitting component layer remains unchanged, so that a part of light-emitting components 36 at the light-emitting component layer are distributed in the first display region 211, and another part of light-emitting components 36 at the light-emitting component layer are distributed in the second display region 212a located on the first side.

When each pixel drive circuit 321 is retracted toward the second side of the display panel 20, and the position of the light-emitting component 36 remains unchanged, there is no overlapping region between orthographic projections of a part of light-emitting components 36 on a substrate 31 and orthographic projections of pixel drive circuits 321 connected to the light-emitting components 36 on the substrate 31. Therefore, a bridge wire layer needs to be added between the drive array layer and the light-emitting component layer, and the bridge wire layer includes a plurality of bridge wires 34. The pixel drive circuit 321 and the light-emitting component 36 are connected based on the bridge wire 34. In addition, a first insulation layer 33 is disposed between the bridge wire layer and the drive array layer, and a second insulation layer 35 is disposed between the bridge wire layer and the light-emitting component layer. One end of the bridge wire 34 needs to be connected to the pixel drive circuit 321 through a first via hole penetrating the first insulation layer 33, and the other end of the bridge wire 34 needs to be connected to the light-emitting component 36 through a second via hole penetrating the second insulation layer 35.

In addition, a drive chip 42 is disposed in the binding region 222, and a plurality of fan-out leads 41 are disposed in the fan-out region 221, so that the drive chip 42 is connected to the signal line 322 by using the fan-out lead 41.

When each pixel drive circuit 321 in the display panel 20 is retracted toward the second side of the display panel 20, one end of the fan-out lead 41 located in the fan-out region 221 needs to extend in a direction of the signal line 322 connected to the fan-out lead 41. In this case, because the signal line 322 is distributed only in the first display region 211, the fan-out lead 41 located in the fan-out region 221 needs to pass through the second display region 212a located on the first side, and extend to a boundary between the first display region 211 and the second display region 212a located on the first side. The fan-out lead 41 is connected to the signal line 322 at the boundary between the first display region 211 and the second display region 212a located on the first side. The other end of the fan-out lead 41 located in the fan-out region 221 extends in a direction of the drive chip 42 connected to the fan-out lead 41.

For the display panel 20 shown in FIG. 8, each pixel drive circuit 321 in the display panel 20 is retracted toward the second side of the display panel 20. That is, when each pixel drive circuit 321 in the display panel 20 is retracted upward in the first direction Y, a partial line segment of the fan-out lead 41 may be moved to the second display region 212a located on the first side, so that a size of a line segment of the fan-out lead 41 left in the fan-out region 221 is reduced in the first direction Y, thereby reducing the frame width on the first side of the display panel 20. In this case, the frame width d2 on the first side of the display panel 20 is less than the frame width d1 on the first side of the display panel 10 shown in FIG. 1.

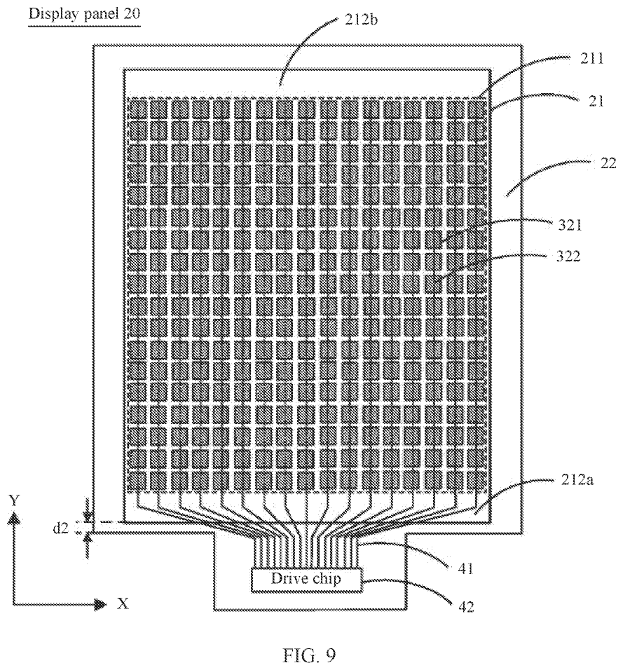

For example, FIG. 9 is a schematic distribution diagram of a pixel drive circuit in a third display panel according to an embodiment of this application. As shown in FIG. 9, a display panel 20 has a display region 21 and a frame region 22 surrounding the display region 21. The display region 21 includes a first display region 211, a second display region 212a located on a first side of the first display region 211, and a second display region 212b located on a second side of the first display region 211. Both the second display region 212a located on the first side and the second display region 212b located on the second side are disposed between the first display region 211 and the frame region 22.

The frame region 22 includes a fan-out region 221 and a binding region 222 that are located on a first side of the display region 21, and the fan-out region 221 is located between the binding region 222 and the display region 21. Specifically, the second display region 212b located on the second side, the first display region 211, the second display region 212a located on the first side, the fan-out region 221, and the binding region 222 are sequentially distributed in a first direction Y.

To reduce a frame width on a first side of the display panel 20, in this embodiment of this application, each pixel drive circuit 321 at a drive array layer is retracted toward a central region of the display panel 20 in the first direction Y, so that the pixel drive circuits 321 and the signal lines 322 are distributed in the first display region 211. However, a position of each light-emitting component 36 at a light-emitting component layer remains unchanged, so that a part of light-emitting components 36 at the light-emitting component layer are distributed in the first display region 211, and another part of light-emitting components 36 at the light-emitting component layer are distributed in the second display region 212a located on the first side and the second display region 212b located on the second side.

When each pixel drive circuit 321 in the display panel 20 is retracted toward the central region of the display panel 20 in the first direction Y, one end of a fan-out lead 41 located in the fan-out region 221 needs to extend in a direction of the signal line 322 connected to the fan-out lead 41. In this case, because the signal line 322 is distributed only in the first display region 211, the fan-out lead 41 located in the fan-out region 221 needs to pass through the second display region 212a located on the first side, and extend to a boundary between the first display region 211 and the second display region 212a located on the first side. The fan-out lead 41 is connected to the signal line 322 at the boundary between the first display region 211 and the second display region 212a located on the first side. The other end of the fan-out lead 41 located in the fan-out region 221 extends in a direction of the drive chip 42 connected to the fan-out lead 41.

For the display panel 20 shown in FIG. 9, when each pixel drive circuit 321 in the display panel 20 is retracted toward the central region of the display panel 20 in the first direction Y, a partial line segment of the fan-out lead 41 may be moved to the second display region 212a located on the first side, so that a size of a line segment of the fan-out lead 41 left in the fan-out region 221 is reduced in the first direction Y, thereby reducing the frame width on the first side of the display panel 20. In addition, when each pixel drive circuit 321 is retracted toward the central region of the display panel 20 in the first direction Y a clock signal line that is originally located in a frame region on a second side of the display panel may be moved to the second display region 212b on the second side, to reduce the frame width on the second side of the display panel 20.

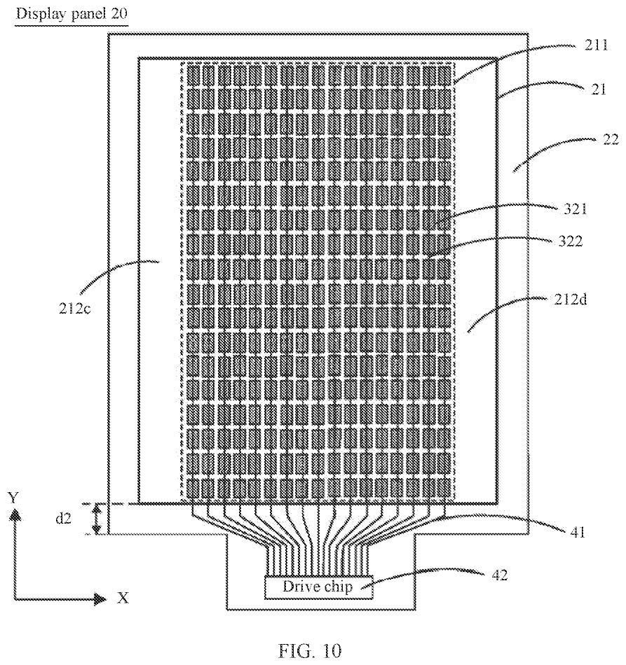

For example, FIG. 10 is a schematic distribution diagram of a pixel drive circuit in a fourth display panel according to an embodiment of this application. As shown in FIG. 10, a display panel 20 has a display region 21 and a frame region 22 surrounding the display region 21. The display region 21 includes a first display region 211, a second display region 212c located on a third side of the first display region 211, and a second display region 212d located on a fourth side of the first display region 211. Both the second display region 212c located on the third side and the second display region 212d located on the fourth side are disposed between the first display region 211 and the frame region 22.

The frame region 22 includes a fan-out region 221 and a binding region 222 that are located on a first side of the display region 21, and the fan-out region 221 is located between the binding region 222 and the first display region 211.

To reduce a frame width on a first side of the display panel 20, in this embodiment of this application, each pixel drive circuit 321 at a drive array layer is retracted toward a central region of the display panel 20 in a second direction X, so that the pixel drive circuits 321 and the signal lines 322 are distributed in the first display region 211. However, a position of each light-emitting component 36 at a light-emitting component layer remains unchanged, so that a part of light-emitting components 36 at the light-emitting component layer are distributed in the first display region 211, and another part of light-emitting components 36 at the light-emitting component layer are distributed in the second display region 212c located on the third side and the second display region 212d located on the fourth side.

When each pixel drive circuit 321 in the display panel 20 is retracted toward the central region of the display panel 20 in the second direction X, fan-out leads 41 are distributed only in the fan-out region 221, and are connected to the signal line 322 at a boundary between the fan-out region 221 and the first display region 211.

For the display panel 20 shown in FIG. 10, when each pixel drive circuit 321 in the display panel 20 is retracted toward the central region of the display panel 20 in the second direction X, an included angle between the first direction Y and an oblique line segment of the fan-out lead 41 connected to each signal line 322 close to an edge of the display region 21 may be reduced, so that the oblique line segment of the fan-out lead 41 connected to each signal line close to the edge of the display region 21 is closer to the first display region 211 in the first direction Y, thereby reducing the frame width on the first side of the display panel 20. In addition, when each pixel drive circuit 321 is retracted toward the central region of the display panel 20 in the second direction X, a GOA circuit that is originally located in a frame region on a third side and/or a fourth side of the display panel may be further moved to the second display region 212c on the third side and the second display region 212d on the fourth side, to reduce frame widths on the third side and the fourth side of the display panel 20.

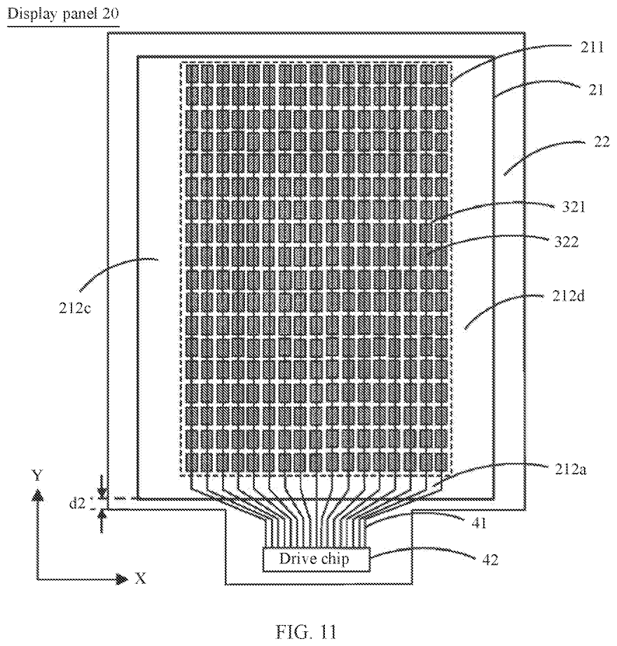

For example, FIG. 11 is a schematic distribution diagram of a pixel drive circuit in a fifth display panel according to an embodiment of this application. As shown in FIG. 11, a display panel 20 has a display region 21 and a frame region 22 surrounding the display region 21. The display region 21 includes a first display region 211, a second display region 212a located on a first side of the first display region 211, a second display region 212c located on a third side of the first display region 211, and a second display region 212d located on a fourth side of the first display region 211. The second display region 212a located on the first side, the second display region 212c located on the third side, and the second display region 212d located on the fourth side are all disposed between the first display region 211 and the frame region 22.

The frame region 22 includes a fan-out region 221 and a binding region 222 that are located on a first side of the display region 21, and the fan-out region 221 is located between the binding region 222 and the first display region 211. Specifically, the first display region 211, the second display region 212a located on the first side, the fan-out region 221, and the binding region 222 are sequentially distributed in a first direction Y.

To reduce a frame width on a first side of the display panel 20, in this embodiment of this application, each pixel drive circuit 321 at a drive array layer is retracted toward a central region of the display panel 20 in a second direction X, and each pixel drive circuit 321 is retracted toward a second side of the display panel 20, so that the pixel drive circuits 321 and the signal lines 322 are distributed in the first display region 211. However, a position of each light-emitting component 36 at a light-emitting component layer remains unchanged, so that a part of light-emitting components 36 at the light-emitting component layer are distributed in the first display region 211, and another part of light-emitting components 36 at the light-emitting component layer are distributed in the second display region 212a located on the first side, the second display region 212c located on the third side, and the second display region 212d located on the fourth side.

When each pixel drive circuit 321 in the display panel 20 is retracted toward the central region of the display panel 20 in the second direction X, and each pixel drive circuit 321 is further retracted toward the second side of the display panel 20, a fan-out lead 41 located in the fan-out region 221 passes through the second display region 212a located on the first side, and extends to a boundary between the first display region 211 and the second display region 212a located on the first side. The fan-out lead 41 is connected to the signal line 322 at the boundary between the first display region 211 and the second display region 212a located on the first side.

For the display panel 20 shown in FIG. 11, when each pixel drive circuit 321 in the display panel 20 is retracted toward the central region of the display panel 20 in the second direction X, and each pixel drive circuit 321 is further retracted toward the second side of the display panel 20, frame widths on the first side, the third side, and the fourth side of the display panel 20 may be reduced.

Certainly, it may be understood that the second display region in the display region 21 may be located on any three sides of the first display region 211.

For example, the display region 21 includes a first display region 211, a second display region 212a located on a first side of the first display region 211, a second display region 212b located on a second side of the first display region 211, and a second display region 212c located on a third side of the first display region 211. In this case, the fan-out lead 41 located in the fan-out region 221 passes through the second display region 212a located on the first side, and extends to a boundary between the first display region 211 and the second display region 212a located on the first side. Alternatively, the display region 21 includes a first display region 211, a second display region 212a located on a first side of the first display region 211, a second display region 212b located on a second side of the first display region 211, and a second display region 212d located on a fourth side of the first display region 211. In this case, the fan-out lead 41 located in the fan-out region 221 passes through the second display region 212a located on the first side, and extends to a boundary between the first display region 211 and the second display region 212a located on the first side. Alternatively, the display region 21 includes a first display region 211, a second display region 212b located on a second side of the first display region 211, a second display region 212c located on a third side of the first display region 211, and a second display region 212d located on a fourth side of the first display region 211. In this case, the fan-out lead 41 is distributed only in the fan-out region 221, and is connected to the signal line 322 at a boundary between the fan-out region 221 and the first display region 211.

In conclusion, the pixel drive circuit 321 is retracted, so that the pixel drive circuit 321 and the signal line 322 are disposed only in the first display region 211 of the display panel 20, and the pixel drive circuit 321 and the signal line 322 are not disposed in the second display region. Therefore, when the signal line 322 in the first display region 211 is connected to the drive chip 42 by using the fan-out lead 41, a size of the fan-out lead 41 located in the fan-out region 221 is reduced in the first direction Y, thereby reducing the frame width on the first side of the display panel 20.

It should be noted that, to clearly show distribution positions of each pixel drive circuit 321, the signal line 322, the fan-out lead 41, and the drive chip 42 in the display panel 20, only each pixel drive circuit 321, the signal line 322, the fan-out lead 41, and the drive chip 42 in the display panel 20 are shown in FIG. 8 to FIG. 11, and the light-emitting component 36 in the display panel 20 is not shown. It may be understood that for specific distribution of the light-emitting component 36 included in the display panel 20 in FIG. 8 to FIG. 11, refer to the distribution position of the light-emitting component 36 shown in FIG. 3, where the light-emitting component 36 is distributed in the entire display region 21.

In an actual manufacture process, to retract the pixel drive circuit 321, an implementation is as follows: When all transistors in the pixel drive circuit 321 are disposed at a same layer, in a direction from the second display region to the first display region 211, namely, in a direction in which the pixel drive circuit 321 is retracted, a sum of a size of the pixel drive circuit 321 and a size of a gap between two adjacent pixel drive circuits 321 is less than a sum of a size of the light-emitting component 36 and a size of a pixel defining structure 364 between two adjacent light-emitting components 36.

When the pixel drive circuit 321 is retracted in the first direction Y, a sum of sizes of the pixel drive circuit 321 and a gap between two adjacent pixel drive circuits 321 in the first direction Y is less than a sum of sizes of the light-emitting component 36 and a pixel defining structure 364 between two adjacent light-emitting components 36 in the first direction Y. When the pixel drive circuit 321 is retracted in the second direction X, a sum of sizes of the pixel drive circuit 321 and a gap between two adjacent pixel drive circuits 321 in the second direction X is less than a sum of sizes of the light-emitting component 36 and a pixel defining structure 364 between two adjacent light-emitting components 36 in the second direction X.

For example, in the direction in which the pixel drive circuit 321 is retracted, sizes of at least a part of transistors in the pixel drive circuit 321 may be reduced, so that sizes of all the pixel drive circuits 321 are reduced in the retraction direction. Therefore, when it is ensured that a position of each light-emitting component 36 remains unchanged, the sizes of all the pixel drive circuits 321 in the retraction direction are less than sizes of all the light-emitting components 36 in the retraction direction.

To retract the pixel drive circuit 321, another implementation is follows: When it is ensured that a size of each transistor in the pixel drive circuit 321 remains unchanged, the transistors in the pixel drive circuit 321 are disposed at different layers. In this case, each pixel drive circuit 321 includes a first transistor group and a second transistor group, the first transistor group and the second transistor group each include at least one transistor, the second transistor group is disposed on a side that is of the first transistor group and that is away from the substrate 31, and an orthographic projection of each transistor in the second transistor group on the substrate 31 and an orthographic projection of each transistor in the first transistor group on the substrate 31 have an overlapping region.

When the transistors in the pixel drive circuit 321 are disposed at different layers, and the orthographic projection of each transistor in the second transistor group on the substrate 31 and the orthographic projection of each transistor in the first transistor group on the substrate 31 have an overlapping region, an area occupied by the orthographic projection of each pixel drive circuit 321 on the substrate 31 is reduced. Therefore, when it is ensured that a position of each light-emitting component 36 remains unchanged, areas occupied by all the pixel drive circuits 321 are less than areas occupied by all the light-emitting components 36.

Optionally, a region surrounded by the orthographic projection of each transistor in the second transistor group on the substrate 31 is located in a region surrounded by the orthographic projection of each transistor in the first transistor group on the substrate 31. Alternatively, a region surrounded by the orthographic projection of each transistor in the first transistor group on the substrate 31 is located in a region surrounded by the orthographic projection of each transistor in the second transistor group on the substrate 31.

It may be understood that the size of each pixel drive circuit 321 in the retraction direction may be reduced in another manner. Therefore, when it is ensured that the position of each light-emitting component 36 remains unchanged, the sizes of all pixel drive circuits 321 in the retraction direction are less than the sizes of all the light-emitting components 36 in the retraction direction.

In some embodiments, the bridge wire layer includes at least one wire layer. When the bridge wire layer includes one wire layer, all the bridge wires 34 are disposed at a same layer. When the bridge wire layer includes at least two wire layers, each wire layer includes a plurality of bridge wires 34, the bridge wires 34 at each wire layer are connected to a part of pixel drive circuits 321 and a part of light-emitting components 36, and any two wire layers are spaced apart by at least one insulation layer.

A material of the bridge wire 34 may be one or more of conductive materials with low transmittance such as copper, aluminum, molybdenum, or silver, or a material of the bridge wire 34 may be a conductive material with high transmittance, for example, a transparent conductive material such as indium tin oxide (Indium tin oxide, ITO).

In some embodiments, there is an overlapping region between the bridge wire 34 connecting the pixel drive circuit 321 and the light-emitting component 36 and a first electrode 361 of another light-emitting component 36, to generate a parasitic capacitance between the bridge wire 34 and the overlapping first electrode 361. When the bridge wire 34 passes through more light-emitting components 36, the generated parasitic capacitance is larger, and a rise speed of a voltage provided by the pixel drive circuit 321 to the bridge wire 34 and the connected first electrode 361 becomes slower.

If quantities of light-emitting components 36 through which different bridge wires 34 pass are not equal, rise speeds of voltages provided by pixel drive circuits 321, connected to the bridge wires 34, to the first electrode 361 are also different. As a result, light-emitting duration of different light-emitting components 36 is different, and light-emitting brightness of different light-emitting components 36 is different, causing non-uniform display brightness of the display panel 20.

Therefore, in this embodiment of this application, when the bridge wire 34 is manufactured, a difference between quantities of light-emitting components 36 through which any two bridge wires 34 pass is set to be less than a preset quantity, to improve uniformity of display brightness of the display panel 20. That the difference is less than the preset quantity may be understood as that quantities of light-emitting components 36 through which any two bridge wires 34 pass are equal or approximately equal. For example, the preset quantity is 2. When a difference between quantities of light-emitting components 36 through which two bridge wires 34 pass is 1, it may be considered that the quantities of light-emitting components 36 through which the two bridge wires 34 pass are approximately equal.

It should be noted that, in this embodiment of this application, a specific value of the preset quantity is not limited, and that the preset quantity is 2 is only used as an example for description above. In addition, when a difference between quantities of light-emitting components 36 through which any two bridge wires 34 pass is set to be less than the preset quantity, wire lengths of the any two bridge wires 34 are relatively close. Because line widths of the bridge wires 34 are basically the consistent, wire resistances of the any two bridge wires 34 may be basically consistent, so that voltage drops obtained after signals provided by the pixel drive circuit 321 are input to the light-emitting components 36 by using the bridge wires 34 are basically consistent.

For example, in FIG. 5, each bridge wire 34 passes through four light-emitting components 36 (which do not include a light-emitting component 36 connected to the bridge wire 34), so that quantities of light-emitting components 36 through which any two bridge wires 34 pass are equal.

In addition, an orthographic projection of each bridge wire 34 on the substrate 31 is any one or a combination of a plurality of a straight line, a broken line, and a curve. The broken line may be a jagged line or the like, and the curve may be a wavy line or the like.

For example, the orthographic projection of the bridge wire 34 on the substrate 31 is a straight line, or the orthographic projection of the bridge wire 34 on the substrate 31 is a broken line, or the orthographic projection of the bridge wire 34 on the substrate 31 is a curve, or the orthographic projection of the bridge wire 34 on the substrate 31 is a combination of a broken line and a curve. A shape of the orthographic projection of the bridge wire 34 on the substrate 31 is not limited in this embodiment of this application.

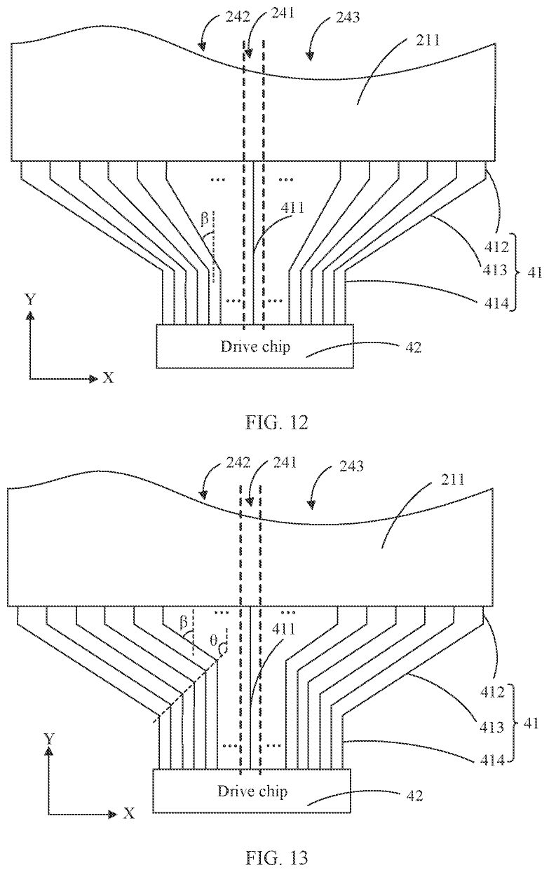

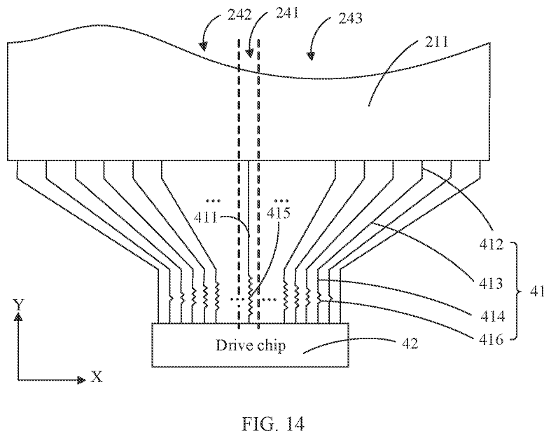

For example, FIG. 12 is a partial enlarged schematic view of a first fan-out lead according to an embodiment of this application, and FIG. 13 is a partial enlarged schematic view of a second fan-out lead according to an embodiment of this application. As shown in FIG. 12 and FIG. 13, a total distribution region of the fan-out lead 41 in the display panel 20 includes a central sub-region 241 and a first edge sub-region 242 and a second edge sub-region 243 that are located on two sides of the central sub-region 241. The first edge sub-region 242, the central sub-region 241, and the second edge sub-region 243 are sequentially distributed in the second direction X.

When the second display region in the display region 11 includes a second display region 212a located on the first side, the total distribution region of the fan-out lead 41 in the display panel 20 is the fan-out region 221 and the second display region 212a located on the first side. When the second display region in the display region 11 does not include a second display region 212a located on the first side, the total distribution region of the fan-out lead 41 in the display panel 20 is the fan-out region 221.

The fan-out lead 41 in the central sub-region 241 includes a first straight line segment 411 extending in the first direction Y. The fan-out leads 41 in the first edge sub-region 242 and the second edge sub-region 243 each include a second straight line segment 412, an oblique line segment 413, and a third straight line segment 414 that are sequentially connected. The second straight line segment 412 and the third straight line segment 414 both extend in the first direction Y. The second straight line segment 412 is close to the first display region 211. The third straight line segment 414 is close to the binding region 222. An included angle β between the oblique line segment 413 and the first direction Y is an acute angle. An obtuse angle formed between the second straight line segment 412 and the oblique line segment 413 is a supplementary angle of the included angle β.

Certainly, in some display panels 20, the included angle β between the oblique line segment 413 and the first direction Y may be a right angle. In this case, the oblique line segment 413 extends in the second direction X.

In an optional implementation, included angles between the oblique line segments 413 of the fan-out leads 41 and the first direction Y may not be equal. As shown in FIG. 12, included angles between the oblique line segments 413 of the fan-out leads 41 in the first edge sub-region 242 and the first direction Y gradually increase in a direction from the central sub-region 241 to the first edge sub-region 242, and included angles between the oblique line segments 413 of the fan-out leads 41 in the second edge sub-region 243 and the first direction Y gradually increase in a direction from the central sub-region 241 to the second edge sub-region 243.

In this case, for the fan-out leads 41 in the first edge sub-region 242 and the second edge sub-region 243, a line segment formed by connection points between the second straight line segments 412 and the oblique line segments 413 is parallel to the second direction X, and a line segment formed by connection points between the third straight line segments 414 and the oblique line segments 413 is also parallel to the second direction X.

It should be noted that the first edge sub-region 242 and the second edge sub-region 243 may be mirror-symmetric, so that included angles between the first direction Y and oblique line segments 413 of two fan-out leads 41 that are symmetrically disposed along the central sub-region 241 and that are respectively located in the first edge sub-region 242 and the second edge sub-region 243 are equal.

In another optional implementation, as shown in FIG. 13, included angles between the first direction Y and the oblique line segments 413 of the fan-out leads 41 in the first edge sub-region 242 and the second edge sub-region 243 are equal. In this case, the oblique line segments 413 of the fan-out leads 41 in the first edge sub-region 242 are parallel, and the oblique line segments 413 of the fan-out leads 41 in the second edge sub-region 243 are also parallel.

For the fan-out leads 41 in the first edge sub-region 242 and the second edge sub-region 243, a line segment formed by connection points between the second straight line segments 412 and the oblique line segments 413 is parallel to the second direction X, and an included angle θ between the first direction Y and a line segment formed by connection points between the third straight line segments 414 and the oblique line segments 413 is an obtuse angle.

Certainly, for the fan-out leads 41 in the first edge sub-region 242 and the second edge sub-region 243, an included angle between the first direction Y and the line segment formed by the connection points between the second straight line segments 412 and the oblique line segments 413 may be an acute angle, and the line segment formed by the connection points between the third straight line segments 414 and the oblique line segments 413 is parallel to the second direction X.

It should be noted that the first edge sub-region 242 and the second edge sub-region 243 may be mirror-symmetric, so that included angles between the first direction Y and line segments formed by connection points between third straight line segments 414 and oblique line segments 413 of two fan-out leads 41 that are symmetrically disposed along the central sub-region 241 are equal.

FIG. 12 and FIG. 13 provide specific schematic distribution diagrams of two different fan-out leads 41. Certainly, it may be understood that distribution of the fan-out lead 41 in this embodiment of this application is not limited to the schematic distribution diagrams shown in FIG. 12 and FIG. 13.

In addition, in the fan-out lead 41 shown in FIG. 12 and FIG. 13, because positions of different signal lines 322 relative to the drive chip 42 are different, the fan-out leads 41 have different wire lengths. Generally, a fan-out lead 41 located in the central sub-region 241 has a shortest length, lengths of the fan-out leads 41 in the first edge sub-region 242 gradually increase in a direction from the central sub-region 241 to the first edge sub-region 242, and lengths of the fan-out leads 41 in the second edge sub-region 243 also gradually increase in a direction from the central sub-region 241 to the second edge sub-region 243.

A length difference between the fan-out leads 41 causes different resistance values of the fan-out leads 41, and a larger length difference between the fan-out leads 41 indicates a larger difference between resistance values. When a difference between resistance values of the fan-out leads 41 in the display panel 20 is larger, a phenomenon such as color cast and non-uniform brightness of a display picture may occur in a display process, and a display effect is affected.

Therefore, in this embodiment of this application, a difference between resistance values of any two fan-out leads 41 needs to be set to be less than a preset resistance value, to alleviate a problem of color cast and non-uniform brightness of a display picture in a display process, and improve a display effect.

That the difference between the resistance values of any two fan-out leads 41 is less than the preset resistance value may be understood as that the resistance values of the any two fan-out leads 41 are equal or approximately equal. For example, the preset resistance value is 10Ω. When a difference between resistance values of two fan-out leads 41 is 9Ω, it may be considered that the resistance values of the two fan-out leads 41 are approximately equal.

It should be noted that, in this embodiment of this application, a specific value of the preset resistance value is not limited, and that the preset resistance value is 10Ω is only used as an example for description above.

To set resistance values of any two fan-out leads 41 to be equal or approximately equal, in an optional implementation, line widths of the fan-out leads 41 are set to be consistent, and a fan-out lead 41 with a short length is wound, so that lengths of the fan-out leads 41 in the display panel 20 are basically consistent, to set the difference between the resistance values of the any two fan-out leads 41 to be less than the preset resistance value.

As shown in FIG. 14, line widths of the fan-out leads 41 are equal. The fan-out lead 41 in the central sub-region 241 further include a first winding segment 415 connected to the first straight line segment 411, at least a part of the fan-out leads 41 in the first edge sub-region 242 and the second edge sub-region 243 each further include a second winding segment 416, and the second winding segment 416 is connected to the third straight line segment 414.

For example, the first winding segment 415 may be connected to an end that is of the first straight line segment 411 and that faces the drive chip 42. Alternatively, the first winding segment 415 may be connected to an end that is of the first straight line segment 411 and that faces the first display region 211. Alternatively, the first straight line segment 411 includes two sub-line segments that are spaced apart, and the first winding segment 415 is located between the two sub-line segments that are spaced apart and that are included in the first straight line segment 411, and is connected to an end of each of the two sub-line segments that are spaced apart. Correspondingly, the second winding segment 416 may be connected to an end that is of the third straight line segment 414 and that faces the drive chip 42. Alternatively, the second winding segment 416 may be connected to an end that is of the third straight line segment 414 and that faces the first display region 211. Alternatively, the third straight line segment 414 includes two sub-line segments that are spaced apart, and the second winding segment 416 is located between the two sub-line segments that are spaced apart and that are included in the third straight line segment 414, and is connected to an end of each of the two sub-line segments that are spaced apart.

Certainly, the second winding segment 416 may be connected to the second straight line segment 412. Alternatively, the second winding segment 416 may be connected to the oblique line segment 413. For a manner of connecting the second winding segment 416 to the second straight line segment 412 or the oblique line segment 413, refer to the manner of connecting the second winding segment 416 to the third straight line segment 414.

To set the lengths of the fan-out leads 41 in the display panel 20 to be basically consistent, a length of the first winding segment 415 needs to be greater than a length of the second winding segment 416. Lengths of the second winding segments 416 of the fan-out leads 41 in the first edge sub-region 242 gradually decrease in a direction from the central sub-region 241 to the first edge sub-region 242, and lengths of the second winding segments 416 of the fan-out leads 41 in the second edge sub-region 243 also gradually decrease in a direction from the central sub-region 241 to the second edge sub-region 243.

To set resistance values of any two fan-out leads 41 to be equal or approximately equal, in another optional implementation, a length of the fan-out lead 41 is not changed, but a line width of the fan-out lead 41 is changed.

Line widths of the fan-out leads 41 in the first edge sub-region 242 gradually increase in a direction from the central sub-region 241 to the first edge sub-region 242, and line widths of the fan-out leads 41 in the second edge sub-region 243 gradually increase in a direction from the central sub-region 241 to the second edge sub-region 243.

Generally, a material of the signal line 322 is one or more of conductive materials such as copper, aluminum, molybdenum, or silver, and has low transmittance. When the display panel is in a screen-off state and external ambient light is irradiated on the display panel 20, the signal line 322 is prone to reflection.

Therefore, to alleviate a reflection problem of the display panel 20 in a screen-off state, orthographic projections of each light-emitting component 36 distributed in the first direction Y and a pixel defining structure 364 between two adjacent light-emitting components 36 in the first direction Y on the substrate 31 cover an orthographic projection of the signal line 322 on the substrate 31.

In this case, the light-emitting components 36 distributed in the first direction Y cover most line segments of the signal lines 322, so that reflection of external ambient light by the signal line 322 is reduced, and reflection of the display panel 20 in a screen-off state is alleviated.

Certainly, the signal line 322 may be manufactured by using a transparent conductive material, to reduce reflectivity of the signal line 322 to external ambient light, thereby alleviating a reflection problem of the display panel 20 in a screen-off state. In this case, the signal line 322 may be located between two adjacent columns of light-emitting components 36, or may be located in a region in which a same column of light-emitting components 36 are located.

It should be noted that, in an actual manufacture process, a process error is unavoidable. Therefore, in the embodiments of this application, “equal” should be understood as “equal” within an allowable process error range, “parallel” should be understood as “parallel” within an allowable process error range, and “vertical” should be understood as “vertical” within an allowable process error range.

The foregoing implementations, schematic diagrams of structures, or schematic simulation diagrams are merely schematic descriptions of the technical solutions of this application, and size ratios do not constitute a limitation on the protection scope of the technical solutions. Any modification, equivalent replacement, and improvement made within the spirit and principle of the foregoing implementations shall be included within the protection scope of the technical solutions.

1. A display panel, comprising:
a frame region;
a display region surrounded by the frame region, wherein the display region includes a first display region and a second display region, wherein the second display region is located on at least one side of the first display region, and is located between the first display region and the frame region;
a drive array layer comprising a plurality of pixel drive circuits and a plurality of signal lines extending in a first direction, wherein each signal line is connected to pixel drive circuits located in a same column, and wherein the pixel drive circuits and the signal lines at the drive array layer are distributed in the first display region;
a light-emitting component layer comprising a plurality of light-emitting components, wherein a first portion of the light-emitting components are located in the first display region, and wherein a second portion of the light-emitting components are located in the second display region; and
a bridge wire layer comprising a plurality of bridge wires, wherein each bridge wire is connected to the pixel drive circuit through a first via hole penetrating a first insulation layer, and wherein each bridge wire is further connected to the light-emitting component through a second via hole penetrating a second insulation layer,
wherein the drive array layer, the first insulation layer, the bridge wire layer, the second insulation layer, and the light-emitting component layer are stacked on a substrate
wherein the frame region comprises a fan-out region and a binding region that are located on a first side of the display region,
wherein the fan-out region is located between the binding region and the display region,
wherein a plurality of fan-out leads are disposed in the fan-out region,
wherein a drive chip is disposed in the binding region, and
wherein one end of the fan-out lead extends in a direction of the signal line connected to the fan-out lead, and the other end of the fan-out lead extends in a direction of the drive chip connected to the fan-out lead.

2. The display panel of claim 1, wherein the second display region is located on a first side of the first display region, and wherein the fan-out lead passes through the second display region, and extends to a boundary between the first display region and the second display region.

3. The display panel of claim 1, wherein the second display region is located on each of a first side and a second side of the first display region, wherein the first side and the second side are opposite to each other, and wherein the fan-out lead passes through the second display region located on the first side, and extends to a boundary between the first display region and the second display region located on the first side.

4. The display panel of claim 1, wherein the second display region is located on each of a third side and a fourth side of the first display region, wherein the third side and the fourth side are opposite to each other, wherein both the third side and the fourth side are adjacent to the first side, and wherein the fan-out lead is distributed in the fan-out region, and is connected to the signal line at a boundary between the fan-out region and the first display region.

5. The display panel of claim 1, wherein the second display region is located on three sides of the first display region, and wherein either a) the display region comprises at least the second display region located on a first side of the first display region, and wherein the fan-out lead passes through the second display region located on the first side, and extends to a boundary between the first display region and the second display region located on the first side; or b) the display region comprises the second display regions located on a second side, a third side, and a fourth side of the first display region, and wherein the fan-out lead is distributed in the fan-out region, and is connected to the signal line at a boundary between the fan-out region and the first display region.

6. The display panel of claim 1, wherein the second display region surrounds the first display region, and wherein the fan-out lead passes through the second display region located on the first side, and extends to a boundary between the first display region and the second display region located on the first side.

7. The display panel of claim 1, wherein a difference between quantities of light-emitting components through which any two bridge wires pass is less than a preset quantity.

8. The display panel of claim 1, wherein an orthographic projection of each bridge wire on the substrate is a straight line, a broken line, a curve, or a combination thereof.

9. The display panel of claim 1, wherein a total distribution region of the fan-out lead in the display panel comprises a central sub-region and a first edge sub-region and a second edge sub-region that are located on two sides of the central sub-region, wherein the first edge sub-region, the central sub-region, and the second edge sub-region are sequentially distributed in a second direction, wherein the second direction and the first direction are perpendicular to each other, wherein the fan-out lead in the central sub-region comprises a first straight line segment extending in the first direction, wherein the fan-out leads in the first edge sub-region and the second edge sub-region each comprise a second straight line segment, an oblique line segment, and a third straight line segment that are sequentially connected, wherein the second straight line segment and the third straight line segment both extend in the first direction, wherein the second straight line segment is close to the first display region, wherein the third straight line segment is close to the binding region, and wherein an included angle between the oblique line segment and the first direction is an acute angle.

10. The display panel of claim 9, wherein included angles between the oblique line segments of the fan-out leads in the first edge sub-region and the first direction gradually increase in a direction from the central sub-region to the first edge sub-region, wherein included angles between the oblique line segments of the fan-out leads in the second edge sub-region and the first direction gradually increase in a direction from the central sub-region to the second edge sub-region, and wherein for the fan-out leads in the first edge sub-region and the second edge sub-region, a line segment formed by connection points between the second straight line segments and the oblique line segments is parallel to the second direction, and a line segment formed by connection points between the third straight line segments and the oblique line segments is also parallel to the second direction.

11. The display panel of claim 9, wherein included angles between the first direction and the oblique line segments of the fan-out leads in the first edge sub-region and the second edge sub-region are equal, and wherein for the fan-out leads in the first edge sub-region and the second edge sub-region, a line segment formed by connection points between the second straight line segments and the oblique line segments is parallel to the second direction, and an included angle between the first direction and a line segment formed by the connection points between the third straight line segments and the oblique line segments is an obtuse angle.

12. The display panel of claim 9, wherein a difference between resistance values of any two fan-out leads is less than a preset resistance value.

13. The display panel of claim 12, wherein line widths of the fan-out leads are equal, wherein the fan-out lead in the central sub-region further comprises a first winding segment connected to the first straight line segment, wherein at least a part of fan-out leads in the first edge sub-region and the second edge sub-region further comprise a second winding segment, wherein the second winding segment is connected to any one of the second straight line segment, the oblique line segment, and the third straight line segment, and wherein a length of the first winding segment is greater than a length of the second winding segment, lengths of the second winding segments of the fan-out leads in the first edge sub-region gradually decrease in a direction from the central sub-region to the first edge sub-region, and lengths of the second winding segments of the fan-out leads in the second edge sub-region gradually decrease in a direction from the central sub-region to the second edge sub-region.

14. The display panel of claim 12, wherein line widths of the fan-out leads in the first edge sub-region gradually increase in a direction from the central sub-region to the first edge sub-region, and wherein line widths of the fan-out leads in the second edge sub-region gradually increase in a direction from the central sub-region to the second edge sub-region.

15. The display panel of claim 1, wherein orthographic projections, on the substrate, of each light-emitting component distributed in the first direction and a pixel defining structure between two adjacent light-emitting components in the first direction cover an orthographic projection of the signal line on the substrate.

16. The display panel of claim 1, wherein two adjacent light-emitting components are spaced apart by sing a pixel defining structure, wherein a gap exists between two adjacent pixel drive circuits, wherein transistors comprised in the pixel drive circuit are disposed at a same layer, and wherein in a direction from the second display region to the first display region, a sum of a size of the pixel drive circuit and a size of the gap is less than a sum of a size of the light-emitting component and a size of the pixel defining structure.

17. The display panel of claim 1, wherein each pixel drive circuit comprises a first transistor group and a second transistor group, wherein the first transistor group and the second transistor group each comprise at least one transistor, wherein the second transistor group is disposed on a side that is of the first transistor group and that is away from the substrate, and wherein an orthographic projection of each transistor in the second transistor group on the substrate and an orthographic projection of each transistor in the first transistor group on the substrate have an overlapping region.

18. A terminal device, comprising:
a housing; and
a display panel mounted on the housing, wherein the display panel comprises:
a frame region;
a display region surrounded by the frame region, wherein the display region includes a first display region and a second display region, wherein the second display region is located on at least one side of the first display region, and is located between the first display region and the frame region:
a drive array layer comprising a plurality of pixel drive circuits and a plurality of signal lines extending in a first direction, wherein each signal line is connected to pixel drive circuits located in a same column, and wherein the pixel drive circuits and the signal lines at the drive array layer are distributed in the first display region;
a light-emitting component layer comprising a plurality of light-emitting components, wherein a first portion of the light-emitting components are located in the first display region, and wherein a second portion of the light-emitting components are located in the second display region; and
a bridge wire layer comprising a plurality of bridge wires, wherein each bridge wire is connected to the pixel drive circuit through a first via hole penetrating a first insulation layer, and wherein each bridge wire is further connected to the light-emitting component through a second via hole penetrating a second insulation layer,
wherein the drive array layer, the first insulation layer, the bridge wire layer, the second insulation layer, and the light-emitting component layer are stacked on a substrate
wherein the frame region comprises a fan-out region and a binding region that are located on a first side of the display region,
wherein the fan-out region is located between the binding region and the display region,
wherein a plurality of fan-out leads are disposed in the fan-out region,
wherein a drive chip is disposed in the binding region, and
wherein one end of the fan-out lead extends in a direction of the signal line connected to the fan-out lead, and the other end of the fan-out lead extends in a direction of the drive chip connected to the fan-out lead.

19. The terminal device of claim 18, wherein the second display region is located on a first side of the first display region, and wherein the fan-out lead passes through the second display region, and extends to a boundary between the first display region and the second display region.

20. The terminal device of claim 18, wherein the second display region is located on each of a first side and a second side of the first display region, wherein the first side and the second side are opposite to each other, and wherein the fan-out lead passes through the second display region located on the first side, and extends to a boundary between the first display region and the second display region located on the first side.
